(19) United States
(12) Patent Application Publication
(10) Pub. No.: US 2010/0097058 A1
(43) Pub. Date: Apr. 22, 2010

(54) STRAIN-BASED CARBON NANOTUBE MAGNETOMETER

(75) Inventor: Stephanie A. Getty, Washington, DC (US)

Correspondence Address: NASA GODDARD SPACE FLIGHT CENTER, 8800 GREENBELT ROAD, MAIL CODE 140.1, GREENBELT, MD, 20771, US

(73) Assignee: NASA Headquarters, Washington, DC (US)

(21) Appl. No.: 11/762,915

(22) Filed: Jun. 14, 2007

Related U.S. Application Data
(60) Provisional application No. 60/815,554, filed on Jun. 15, 2006.

(51) Int. Cl. G01R 33/02; C23F 1/02

(52) U.S. Cl. 324/244; 216/22

(57) ABSTRACT

A carbon nanotube magnetometer including a system and method of making the same that includes a single-walled carbon nanotube network formed on a substrate. Electrodes are deposited on opposite ends of the network and a magnetic needle is deposited on the network between the electrodes. A trench is formed under the network in the substrate to facilitate movement of the needle.

### CROSS-REFERENCE TO RELATED APPLICATIONS

The present application claims the benefit of priority of U.S. provisional patent application Ser. No. 60/815,554 filed on Jun. 15, 2006, which is hereby incorporated by reference.

### ORIGIN OF INVENTION

The invention described herein was made by an employee of the United States Government, and may be manufactured and used by or for the Government for governmental purposes without the payment of any royalties thereon or therefor.

### BACKGROUND OF THE INVENTION

A magnetometer is a device for measuring magnetic fields. Many spaced-based mission objectives will rely on the ability to make in situ magnetic field measurements. Magnetometers are of significant utility in attitude control of spacecraft in earth orbit, and in the study of magnetosphere and planetary sciences.

A popular form of magnetometer is the fluxgate magnetometer. The fluxgate magnetometer utilizes a drive coil wound around a toroidal magnetic core, in conjunction with a sense coil. The existing fluxgate design is bulky, relatively massive and consumes precious power.

It is an object of the present invention to provide a magnetometer that is up to five orders of magnitude less in mass than conventional fluxgate magnetometers and consumes up to two to three orders of magnitude less operating power. In addition, the magnetometer of the present invention will enable field measurements in the range of microTeslas, and optimization will enable nanoTesla measurements.

### SUMMARY OF THE INVENTION

In an embodiment of the present invention, a strain-based carbon nanotube magnetometer is presented. In this embodiment, the invention comprises a substrate having a trench therein extending down from a top surface; a carbon nanotube network disposed on the top surface and positioned over the trench; a first electrode connected to one end of the network; a second electrode connected to an opposite end of the network; and a magnetic needle positioned on the network between the electrodes and operable to twist into and out of the trench in response to a magnetic field.

In another embodiment of the present invention, a strain-based carbon nanotube system is presented. In this embodiment, the invention comprises a substrate having a plurality of trenches each extending down from a top surface of the substrate; a plurality of carbon nanotube networks each covering a respective one of the trenches; a plurality of first and second electrodes, the first and second electrodes connected to opposite ends of a respective network; and a plurality of magnetic needles each positioned on a respective one of the networks, each needle being operable to twist into and out of a respective one of the trenches.

In still another embodiment of the present invention, a method of making a carbon nanotube magnetometer is presented. In this embodiment, the invention comprises the steps of providing a substrate; growing a network of carbon nanotubes on the substrate; depositing first and second electrodes on ends of the network; depositing a needle on the substrate between the electrodes; and etching away the substrate below the network.

The invention will be better understood, and features and advantages thereof will become apparent from the following detailed description taken in conjunction with the accompanying drawings.

### BRIEF DESCRIPTION OF THE DRAWINGS

In the drawings, like or corresponding parts are denoted by like or corresponding reference numerals.

FIG. 1 is a plan view of a carbon nanotube magnetometer in accordance with one embodiment of the present invention.

FIG. 2 is a side view of the magnetometer of FIG. 1.

FIG. 3 illustrates an apparatus for forming carbon nanotubes.

FIGS. 4A to 4E illustrate the fabrication of the device of FIG. 1.

FIG. 5 is a graph illustrating resistance versus temperature.

FIG. 6 is a graph illustrating current versus voltage for various values of applied magnetic field.

FIG. 7 illustrates an array of magnetometers.

### DETAILED DESCRIPTION

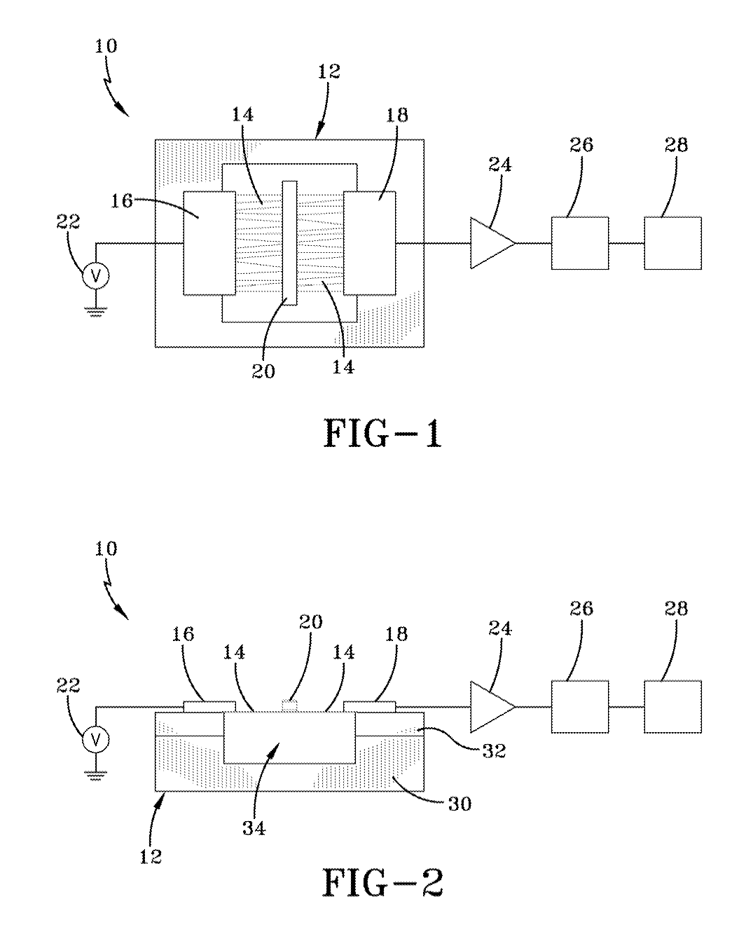

Referring now to FIG. 1, one embodiment is illustrated, showing a strain-based carbon nanotube magnetometer 10 formed on a substrate 12. The magnetometer 10 includes a network 14 of carbon nanotubes connected between electrodes 16 and 18. Electrodes 16 and 18 may comprise gold. A large aspect ratio magnetic needle 20 overlies the carbon nanotubes 14 between electrodes 16 and 18 and may be made of iron, although other metals such as cobalt and nickel, by way of example, may be used. The aspect ratio for the needle 20 may be 1:25 to 1:500, by way of example. Needle 20 may be located midway between the electrodes 16 and 18.

The needle 20 may not withstand some fabrication steps and is subject to oxidation. To protect needle 20, a protective coatings 20a and 20b may be formed on the top and bottom respectively of the needle 20. Protective coatings 20a and 20b may consist of chromium or other suitable coating materials. In operation, in the presence of a magnetic field, the needle 20 will deflect in proportion to the strength of the field. This deflection results in a torque or strain on the network 14. The torque reduces the electrical conductance of the network 14 and the reduction in conductance can be sensed. The network 14 does not have strong magnetic field dependence, thus the magnetic response is dominated by the response of the needle 20.

The sensing of the reduction in conductance is accomplished with the provision of a voltage source 22 connected to electrode 16, in conjunction with a current transconductance amplifier 24 connected to the other electrode 18. An analog-to-digital converter 26 converts the analog output of the current transconductance amplifier 24 to a digital signal for use by a computer 28. By utilizing three devices of the type illustrated in FIG. 1, a vector magnetic field measurement may be made. The voltage source, current amplifier, analog-to-digital converter, and computer could, in principle, be replaced by miniaturized application-specific integrated circuitry (ASIC) components for a system-level spaceflight ready instrument.

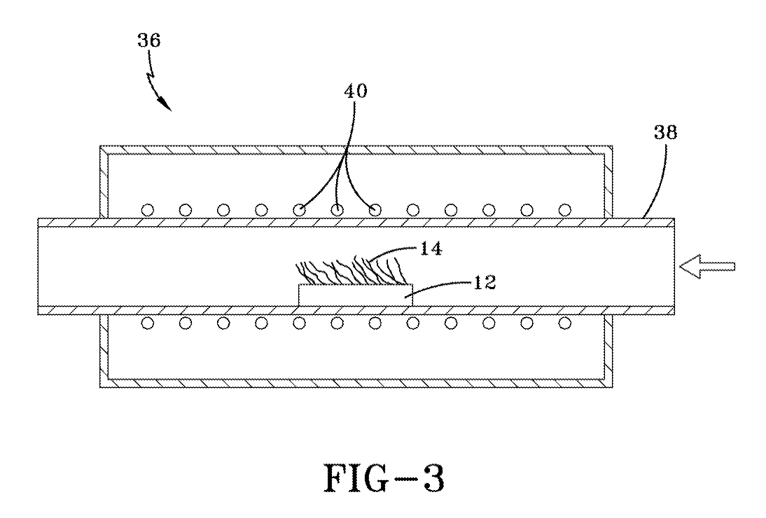

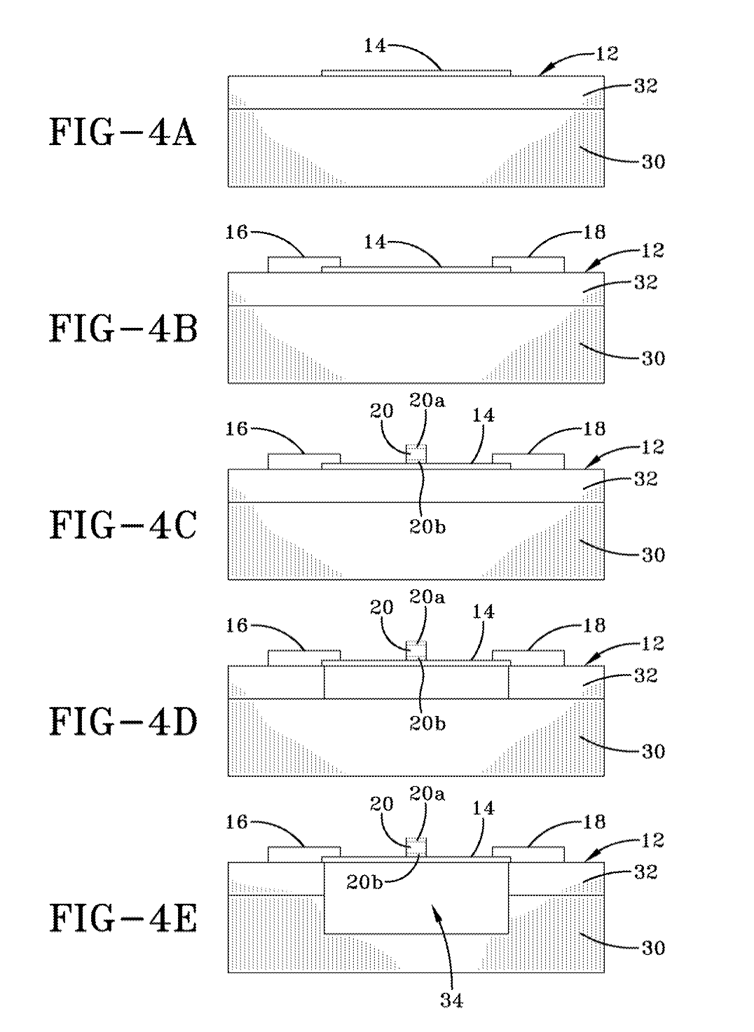

A side view of the device of FIG. 1 is illustrated in FIG. 2. As illustrated in FIG. 2, the substrate 12 is composed of two layers. The first layer 30 is an electrically conducting semiconductor such as silicon while the second layer 32 is an electrically insulating material such as silicon dioxide. The reason for the two different materials will be explained with respect to the manufacturing steps of FIGS. 4A to 4E. The substrate is etched away underneath the network 14 to provide a void or trench 34. The needle 20 has a persistent magnetization based on the fact that it is a ferromagnetic. That being the case, the magnetic dipole wants to align with the magnetic field. This causes a twisting movement of the needle 20 into and out of the trench 34.

The carbon nanotube network 14 may be fabricated by various methods. In one embodiment a CVD (chemical vapor deposition) is utilized. Initially, a sub-monolayer of thin film iron is evaporated onto the surface of substrate 12 in an evaporator to act as a catalyst. The next step in the process is the growing of the carbon nanotubes, as illustrated in FIG. 3. FIG. 3 illustrates a tube furnace 36 through which extends a tube 38. Elevated temperatures are attained within the tube 38 by means of a heater 40 surrounding the tube. Inside the tube 38 is a substrate 12 on which is grown a carbon nanotube network 14.

In an embodiment of the present invention, single-walled carbon nanotubes may be grown as opposed to double-walled carbon nanotubes. To grow the carbon nanotubes the substrate 12 is heated to 950° C. for 5 minutes in flowing feedstock gases that include methane and ethylene at 900 sccm (standard cubic centimeters per minute) units of air for the methane and 80 sccm (air) for the ethylene. At elevated temperatures, the thin film iron on the substrate 12 will liquefy and form hemispherical nanoparticles. Carbon from the feedstock gases dissociates from the hydrogen in the gases and becomes dissolved into the iron nanoparticles. When the iron catalyst becomes saturated with carbon, the carbon starts to form the nanotube end cap at the particle surface and additional dissolved carbon adds to the structure to lengthen the nanotube and eventually form the network 14.

During the growth process argon is introduced into the tube 38 to maintain an inert environment. Hydrogen is also introduced to reduce any iron catalyst that has been oxidized during air handling to its elemental form. That is, the hydrogen ensures that the catalyst is iron and not iron oxide.

FIGS. 4A to 4E illustrate an embodiment that shows the process for making a device as in FIG. 1. FIG. 4A shows the substrate 12 with the network 14, as it would come from the tube furnace 36 of FIG. 3. The structure of FIG. 4A is suitably masked and the gold electrodes 16 and 18 are deposited, as shown in FIG. 4B. With another masking, the needle 20 along with the chromium protective coatings are deposited as in FIG. 4C, leaving a structure ready for etching The relatively thin silicon dioxide substrate layer 32 acts as an insulator to prevent current shunting through the silicon layer 30. After suitable masking, and as illustrated in FIG. 4D, the silicon dioxide is etched away under the network 14 by using an etchant such as hydrogen fluoride.

Although the entire substrate may be made of silicon dioxide, the etching rate through silicon dioxide is relatively slow. Therefore, the silicon dioxide layer is very thin. The etching rate through the thicker silicon layer may be faster than the etching rate through the thinner silicon dioxide layer. The silicon is next etched away with, for example, potassium hydroxide, resulting in the trench 34. As illustrated in FIG. 4E, trench 34 allows needle 20 to twist into and out of the trench 34 thereby straining the network 14.

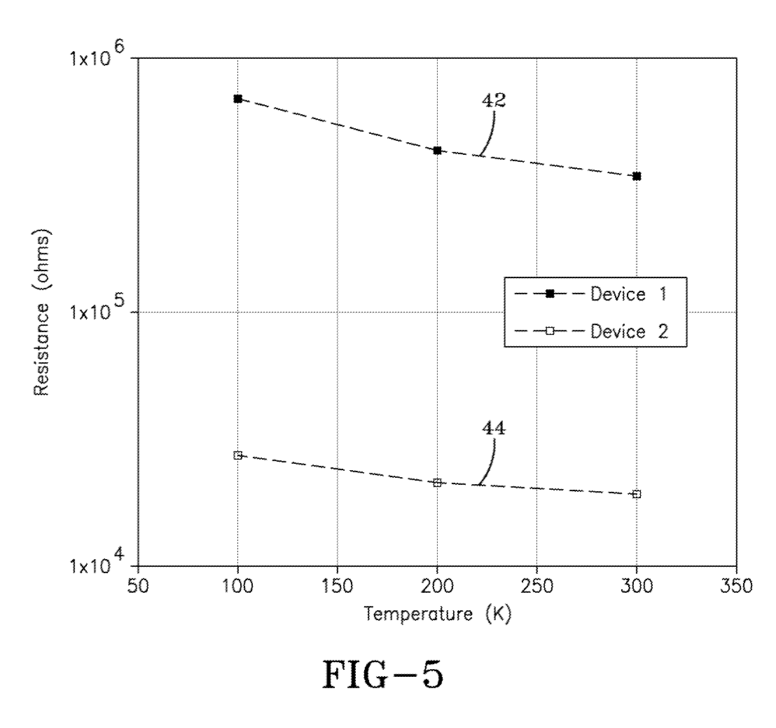

It may be desirable that a magnetometer intended for space-based science be insensitive to thermal fluctuations, such that changes in the incidence of solar radiation do not dramatically affect operation. The magnetometer of the present invention meets this requirement. Graphs 42 and 44 of FIG. 5 illustrate the response of two different magnetometers of the type illustrated in FIG. 1. Resistance in ohms is plotted on the vertical axis and temperature in degrees Kelvin is plotted on the horizontal axis. The plots illustrate a fairly constant and level response for the two devices from room temperature (around 100° K.) out to 300° K.

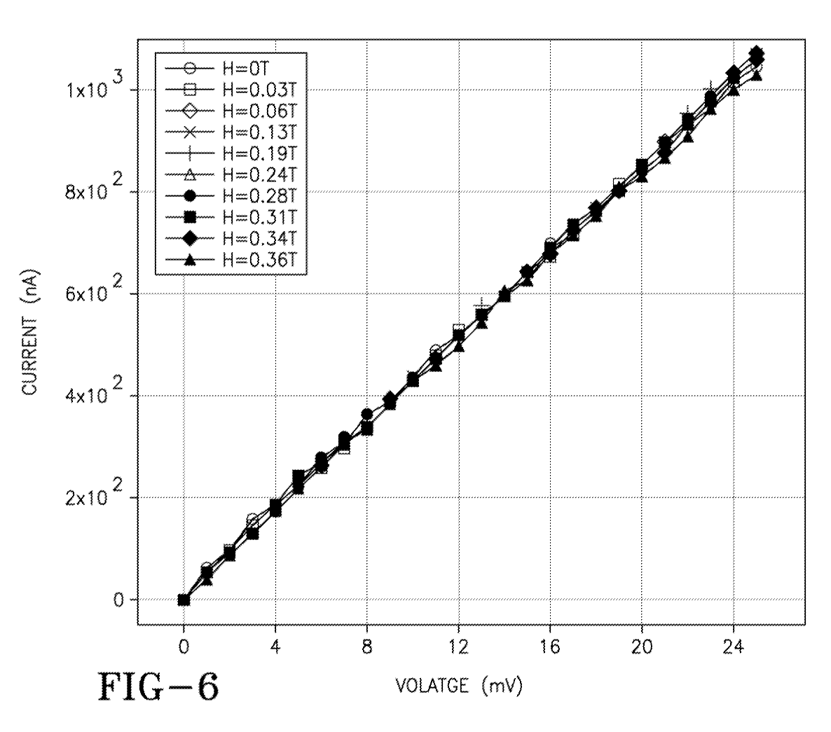

FIG. 6 is a plot illustrating the lack of magnetic field dependence. Current in milliamps is plotted on the vertical axis and voltage in millivolts is plotted on the horizontal axis. Each data point illustrated is actually the result of 10 different magnetic field values ranging from 0 T to 0.36 T in a test performed on a device as in FIG. 1.

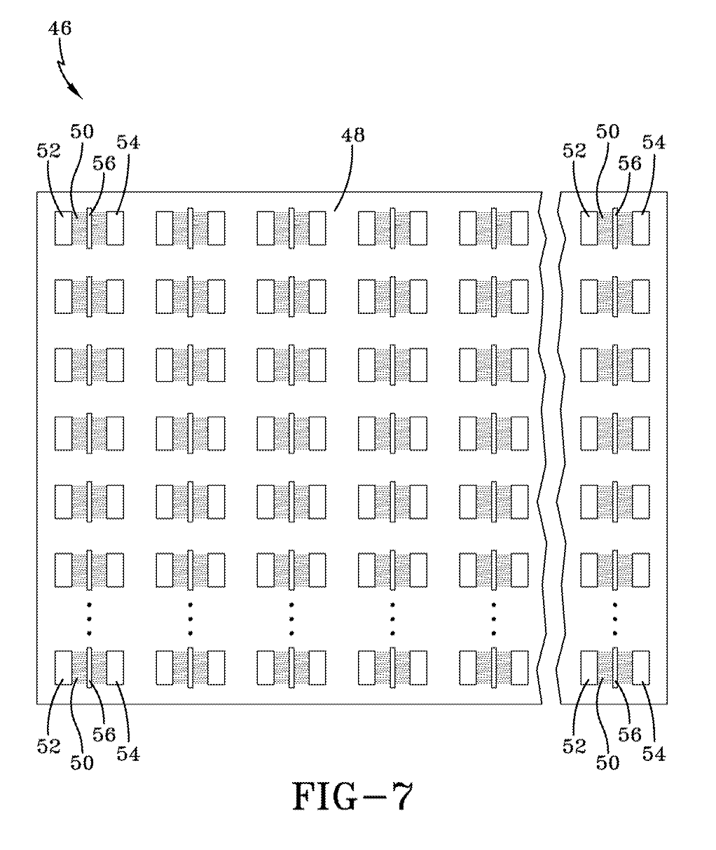

FIG. 7 illustrates yet another embodiment wherein an array 46 of individual carbon nanotube magnetometers on a large substrate 48. Each magnetometer of the array 46 includes a carbon nanotube network 50, first and second electrodes 52 and 54, and a needle 56 disposed between the electrodes. The array 46 may be manipulated to form a plurality of individual magnetometers. The entire array as illustrated in FIG. 7 may be used for various purposes. For example, the array 46 may find utility when the spatial variation of a magnetic field in a particular area is to be studied. There may also be applications in space and planetary science for studying various structures on the micron scale without the need for scanning and for studying highly varying magnetic fields in space. Other applications may include the reading of magnetic data without the need for swiping. The magnetometer can be used in applications where a small, compact low power magnetic field sensor is needed, such as a personal electronic compass in a cell phone or in military applications in a distributed sensor net to monitor movement of vehicles, by way of example.

Various options are available for the growth of the carbon nanotubes on the substrate 48 or the substrate 12 of FIGS. 4A to 4E. One option is to grow the carbon nanotubes over the entire substrate and then deposit the electrodes to define an operating magnetometer while leaving portions of unused network on the substrate. Another option includes trimming the network to size after growth of the carbon nanotubes. In a third option, the thin film iron is deposited only in selected masked areas on the substrate.

Although a few embodiments of the present invention have been shown and described, it may be appreciated by those skilled in the art that changes may be made in these embodiments without departing from the principles and spirit of the invention. Other embodiments of the invention may be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A strain-based carbon nanotube magnetometer comprising:
a substrate having a trench therein extending down from a top surface;
a carbon nanotube network disposed on the top surface and positioned over the trench;
a first electrode connected to one end of the network;
a second electrode connected to an opposite end of the network; and
a magnetic needle positioned on the network between the electrodes and operable to twist into and out of the trench in response to a magnetic field.

2. The magnetometer of claim 1 wherein carbon nanotubes of the network are single-walled carbon nanotubes.

3. The magnetometer of claim 1 wherein the magnetic needle comprises iron.

4. The magnetometer of claim 3 wherein the magnetic needle includes a protective layer on top and bottom surfaces.

5. The magnetometer of claim 4 wherein the protective layer comprises chromium.

6. The magnetometer of claim 1 wherein an aspect ratio of the magnetic needle is from about 1:25 to about 1:500.

7. The magnetometer of claim 1 wherein the magnetic needle is positioned between the first and second electrodes.

8. The magnetometer of claim 1 wherein the first and second electrodes comprise gold.

9. The magnetometer of claim 1 wherein the substrate comprises two layers.

10. The magnetometer of claim 9 wherein a first layer is an electrically conducting semiconductor and a second layer is electrically insulating.

11. The magnetometer of claim 10 wherein the first layer is silicon and the second layer is silicon dioxide.

12. The magnetometer of claim 11 wherein the ends of the network lie on the second layer.

13. The magnetometer of claim 1 further comprising a voltage source connected to the first electrode and a current transconductance amplifier connected to the second electrode.

14. A strain-based carbon nanotube structure, comprising:
a substrate having a plurality of trenches each extending down from a top surface of the substrate;
a plurality of carbon nanotube networks each covering a respective one of said trenches;
a plurality of first and second electrodes, the first and second electrodes connected to opposite ends of a respective network;
a plurality of magnetic needles each positioned on a respective one of the networks, each needle being operable to twist into and out of a respective one of said trenches.

15. A method of making a carbon nanotube magnetometer, comprising:
providing a substrate;
growing a network of carbon nanotubes on the substrate;
depositing first and second electrodes on ends of the network;
depositing a needle on the substrate between the electrodes; and
etching away the substrate below the network.

16. The method of clam 15 wherein the step of growing includes growing the carbon nanotubes by a chemical vapor deposition method.

17. The method of clam 15 wherein the step of providing includes providing a substrate having first and second layers.

18. The method of clam 17 wherein the step of providing includes providing a substrate having a first layer of silicon and a second layer of silicon dioxide.

19. The method of clam 17 wherein the etching step includes etching away the second layer with a first etchant and partially etching away the first layer with a second etchant.

20. The method of claim 19 wherein the etching step includes utilizing hydrogen fluoride as the first etchant and utilizing potassium hydroxide as the second etchant.

21. The method of claim 15 further comprising providing a protective coating on the bottom and top of said needle.

22. The method of claim 21 wherein said protective coating comprises chromium on the bottom and top of said needle.

23. A method of making a carbon nanotube structure, comprising:
providing a substrate;
growing carbon nanotubes on the substrate;
depositing a plurality of first and second electrodes at selected locations on the carbon nanotubes to define carbon nanotube networks between the electrodes;
depositing a plurality of magnetic needles on the networks between respective first and second electrodes; and
etching away the substrate below the networks to facilitate movement of the magnetic needles.
